(19) United States
(12) Patent Application Publication
(10) Pub. No.: US 2020/0091449 A1
(43) Pub. Date: Mar. 19, 2020

(54) FORMING DIELECTRIC FOR ELECTRONIC DEVICES

(71) Applicant: FLEXENABLE LIMITED, Cambridge (GB)

(72) Inventors: Jan Jongman, Cambridge (GB); Romain Futsch, Cambridge (GB)

(73) Assignee: FLEXENABLE LIMITED, Cambridge (GB)

(21) Appl. No.: 16/569,778

(22) Filed: Sep. 13, 2019

(30) Foreign Application Priority Data
Sep. 14, 2018 (GB) 1815017.7

(51) Int. Cl. H01L 51/05; H01L 27/28

(52) U.S. Cl. CPC H01L 51/0529; H01L 27/283; H01L 51/0541; H01L 51/052

(57) ABSTRACT

A method of forming a stack of layers defining one or more electronic devices, the method comprising: depositing a first thickness of curable, dielectric or dielectric precursor material over an area of a workpiece; thereafter exposing the workpiece to curing conditions at least over said area of said workpiece; and without any intermediate patterning operation, thereafter depositing a second thickness of said curable material over said area of said workpiece; and thereafter again exposing the workpiece to curing conditions at least over said area of said workpiece.

The production of a stack of layers together defining one or more electronic devices involves the inclusion within the stack of a dielectric for the one or more electronic devices.

The inventors for the present application have conducted extensive research around forming dielectrics for electronic devices, and have found techniques capable of improving yield.

There is hereby provided a method of forming a stack of layers defining one or more electronic devices, the method comprising: depositing a first thickness of curable, dielectric or dielectric precursor material over an area of a workpiece; thereafter exposing the workpiece to curing conditions at least over said area of said workpiece; and without any intermediate patterning operation, thereafter depositing a second thickness of said curable material over said area of said workpiece; and thereafter again exposing the workpiece to curing conditions at least over said area of said workpiece.

According to one embodiment, said one or more electronic devices include one or more transistors and said dielectric or dielectric precursor material is a gate dielectric or gate dielectric precursor material.

According to one embodiment, exposing the workpiece to curing conditions comprises exposing the workpiece to curing radiation at least over said area of said workpiece.

According to one embodiment, the first and second thicknesses are substantially equal.

According to one embodiment, the curable material is a cross-linkable material, and the curing radiation is at one or more wavelengths that induce cross-linking of the cross-linkable material.

According to one embodiment, the method comprises: after said first curing and before depositing said second thickness of said curable material, subjecting the workpiece to a surface treatment at least over said area of said workpiece.

According to one embodiment, the method comprises: depositing said second thickness of curable material comprises forming a film of a solution of said curable material; and said surface treatment increases the wettability of the surface of the workpiece for said solution of said curable material over said area of said workpiece.

According to one embodiment, said surface treatment comprises exposing the workpiece to a plasma or ultraviolet radiation from an ultraviolet lamp, at least over said area of said workpiece.

According to one embodiment: before depositing said first thickness of curable material, the workpiece includes a semiconductor channel material layer providing the semiconductor channels for said one or more transistors.

According to one embodiment: said semiconductor channel material layer is a patterned layer: forming said patterned semiconductor channel material layer comprises patterning a layer of semiconductor channel material via a dielectric layer; and the method comprises depositing said first thickness of said curable material on said dielectric layer.

There is also hereby provided a method of forming a stack of layers defining one or more electronic devices, the method comprising: depositing a controlled amount of a solution of dielectric material or dielectric precursor material on a workpiece over an area of the workpiece, and thereafter depositing a second controlled amount of said solution of a dielectric material or a dielectric precursor material on the workpiece over said area of the workpiece; wherein prior to depositing said second controlled amount of said solution of dielectric material or dielectric precursor material, subjecting the workpiece to a surface treatment so as to increase the wettability of the surface of the workpiece for said solution of gate dielectric material or gate dielectric precursor material over said area of the workpiece.

According to one embodiment, said one or more electronic devices include one or more transistors and said dielectric or dielectric precursor material is a gate dielectric or gate dielectric precursor material.

According to one embodiment, said surface treatment comprises exposing said workpiece to a plasma or ultraviolet radiation from an ultraviolet lamp.

An embodiment of the present invention is described in detail hereunder, by way of example only, with reference to the accompanying drawings, in which:

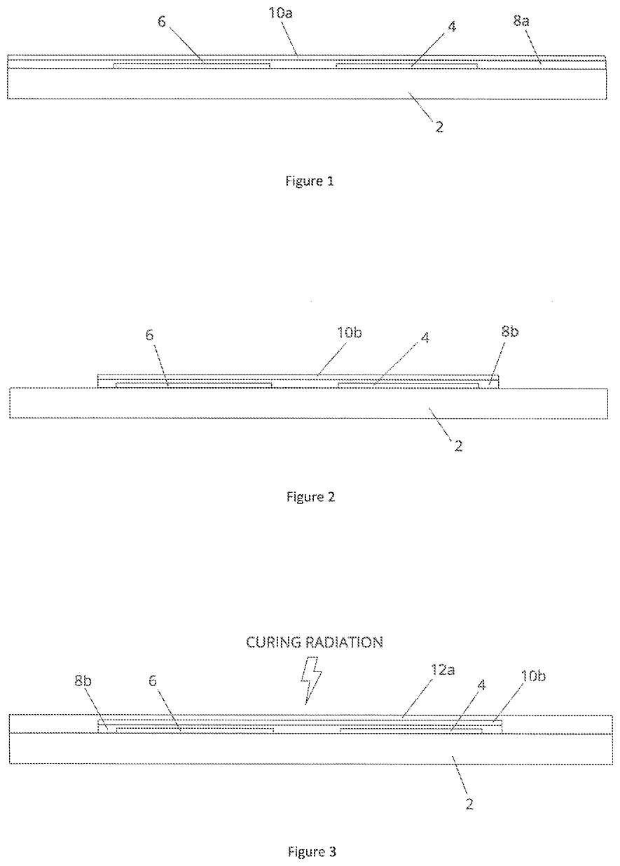

FIGS. 1 and 2 illustrate a semiconductor patterning step prior to an example process according to a first embodiment of the present invention;

FIG. 3 illustrates the formation of a cured gate dielectric layer in the example process according to the first embodiment of the present invention;

FIG. 4 illustrates a surface treatment step of a cured gate dielectric layer in the example process according to the first embodiment of the present invention;

FIG. 5 illustrates the formation of a cured second gate dielectric layer in the example process according to the first embodiment of the present invention;

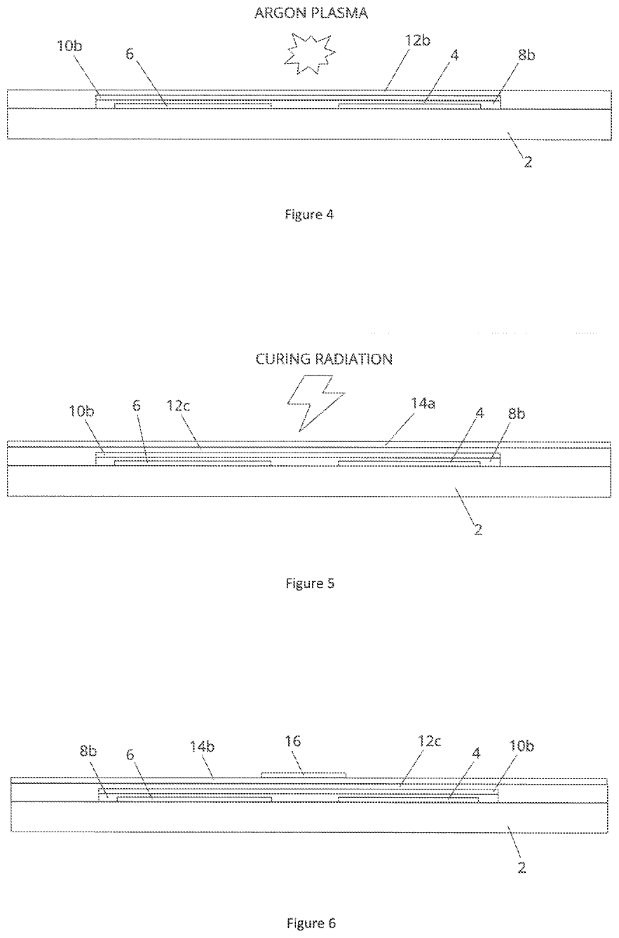

FIG. 6 illustrates the formation of a gate conductor over the second gate dielectric layer from the example process according to the first embodiment of the present invention; and

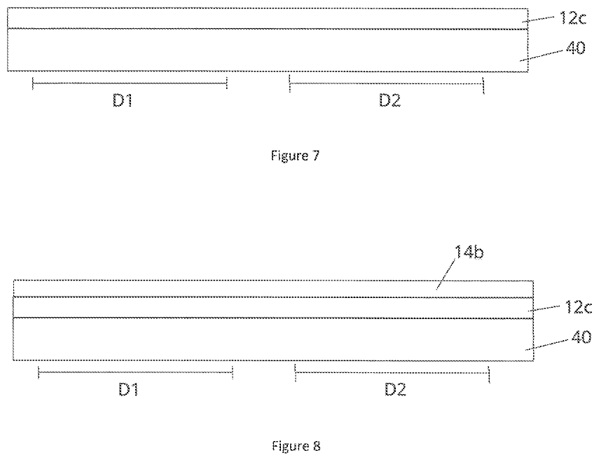

FIGS. 7 and 8 illustrate use of the example process according to the first embodiment in a mass production technique.

A first embodiment of the invention is described in detail below for the example of forming the dielectric for a top-gate transistor device, but the technique is equally applicable to the formation of a dielectric for a bottom-gate transistor device, and to the formation of dielectrics for other types of electronic device that rely on capacitive coupling via a dielectric, such as capacitor devices.

A first embodiment of the invention is described in detail below for the example of forming an array of transistors for controlling an array of pixel electrodes, but the technique is equally applicable to the formation of one or more electronic devices for other functions, such as e.g. transistors and/or capacitors for a logic circuit.

A first embodiment of the invention is described in detail below for the example of forming a gate dielectric over a semiconductor channel material layer patterned via an additional gate dielectric layer, but the technique is equally applicable to the formation of a gate dielectric over a semiconductor channel material layer patterned other than via an additional gate dielectric layer, and to the formation of a gate dielectric over an unpatterned semiconductor channel material layer.

A first embodiment of the invention is described for the example of forming a gate dielectric for one or more transistors including an organic semiconductor channel (referred to as organic thin film transistors (OTFTs)), but the technique is equally applicable to the formation of a gate dielectric for one or more transistors including other types of semiconductor channels.

The first embodiment involves the formation in situ on a (e.g. plastics) support film of a stack of conductor, semiconductor and dielectric layers that together define one or more transistors, such as for example, an array of transistors.

FIGS. 1 and 2 illustrate an example technique for forming a patterned layer 8b of organic polymer semiconductor channel material over a source-drain conductor pattern defining source and drain electrodes 4, 6 for one or more transistors, which is formed in situ on a support element 2. The support element 2 may, for example, comprise a plastics support film on which are formed in situ one or more layers such as e.g. a planarisation layer and/or a moisture barrier layer. FIGS. 1 and 2 only show a single pair of source/drain electrodes, but the source-drain conductor pattern may equally define: (i) an array of source conductors each providing the source electrodes for a respective row of transistors of an active-matrix array of transistors, and each extending beyond the array of transistors; and (ii) an array of drain conductors, each providing the drain electrode for a respective transistor of the array of transistors.

A solution of organic polymer semiconductor channel material is deposited substantially uniformly over a workpiece including the above-described source-drain conductor pattern, by e.g. a spin-coating technique, to form a continuous/unpatterned layer 8a. The formation of this continuous layer 8a of semiconductor channel material may, for example, be preceded by the formation on the source-drain conductor pattern of a self-assembled monolayer of organic material that facilitates the transfer of charge carriers between the source-drain conductor pattern and the semiconductor channel material.

A solution of a dielectric material (or a precursor to a dielectric material) is deposited substantially uniformly over the resulting workpiece (including the continuous layer 8a of organic semiconductor channel material, by e.g. a spin-coating technique, to form a continuous/unpatterned layer. In this example, there is used a curable dielectric material having a lower dielectric constant than the dielectric material deposited later, as discussed below.

The continuous layer 10a of curable dielectric material is patterned by the curing of selective regions of the continuous layer 10a, and developing of the latent solubility image thus created in the continuous layer 10a, to create a mask 10b for patterning the continuous layer of semiconductor channel material 8a by e.g. a reactive ion etching technique. The selective curing of the continuous layer 10a comprises exposing the continuous layer 10a through a patterned photomask to radiation at a wavelength that induces cross-linking in the curable material, which cross-linking reduces solubility in the solvent from which the curable material was deposited.

A controlled amount of a solution of a cross-linkable material is deposited substantially uniformly over an area of the upper, working surface of the resulting workpiece including the patterned semiconductor and dielectric layers 8b, 10b, by e.g. a spin-coating technique, to form a continuous layer 12a. As mentioned below in relation to FIGS. 7 and 8, the area over which the controlled amount of said solution of cross-linkable material is deposited may be the whole area of one side a large area workpiece 40 from which a plurality of transistor array devices are simultaneously produced.

The resulting workpiece is subjected to a baking process to remove solvent and then exposed over at least the area of the continuous layer 12a (and from the side of the workpiece on which the continuous layer 12a was formed) to curing radiation at one or more wavelengths (e.g. ultraviolet (UV) radiation) that induce cross-linking of the cross-linkable material. The resulting workpiece is then subjected to a surface treatment over at least the area of the cured continuous gate dielectric layer 12b, which surface treatment enhances the wettability of the surface of the cured, dielectric layer 12b for the same solution of cross-linkable material. This surface treatment may, for example, involve exposing the workpiece to a plasma (such as an argon plasma) at least over the area of the cured dielectric layer 12b, or exposing the workpiece to ultraviolet (UV) radiation from a UV lamp (e.g. UV at about 254 nm or UV Ozone at about 185 nm), at least over the area of the cured dielectric layer. In this example, the work piece is subject to an additional bake to finish the curing process.

Without any intermediate patterning of the cured and surface-treated dielectric layer 12c (i.e. with retention of the first gate dielectric layer over the whole area over which the solution of the curable material was deposited), without any deposition of any intervening layer, a second controlled amount of the exact same solution of cross-linkable material is deposited substantially uniformly over the same area of the workpiece over which the first controlled amount of the solution of cross-linkable material was deposited, to form a continuous layer 14a directly on the cured and surface-treated dielectric layer 12c. The deposition conditions and deposition technique are the same as for the deposition of the first controlled amount of the solution of cross-linkable material; for example, the same spin-coating technique may be used.

The resulting workpiece is subjected to a baking process to remove solvent, and then exposed over at least the area of the continuous layer 14a (and from the side of the workpiece on which the continuous layer 14a was formed) to curing radiation at one or more wavelengths (e.g. ultraviolet (UV) radiation) that induce cross-linking of the cross-linkable material. In this example, the work piece is again subject to an additional bake to finish the curing process.

Immediately after curing, the resulting cured, dielectric layer 14b occupies substantially all regions occupied by the underlying cured and surface-treated dielectric layer 12c; there are substantially no regions of the workpiece occupied by only one of the two gate dielectric layers 12c, 14b. The technique does not exclude patterning of one or both of the two gate dielectric layers 12c, 14b after the second curing operation, but no patterning of the lower gate dielectric layer is done before forming the upper gate dielectric layer.

In this example, conductor material is deposited substantially uniformly over the upper, working surface of the resulting workpiece, including the upper, cured gate dielectric layer 14b, by e.g. a vapour deposition technique such as sputtering, to form a continuous layer. The continuous layer of conductor material is patterned (by e.g. a photolithographic technique using a temporary resist) to define one or more gate conductors 16 providing the gate electrodes for the one or more transistors. According to another example, a gate conductor pattern is formed by a printing technique.

In the example mentioned above of producing an active-matrix array of transistors, the patterned conductor layer defines an array of gate conductors, each providing the gate electrode for a respective column of transistors of the array of transistors, and each extending beyond the array of transistors. Each drain conductor (which may, for example, form a pixel electrode or be conductively connected to a respective pixel electrode at a higher level within the stack) is associated with a respective unique combination of gate and source conductors, and is independently addressable via the portions of the gate and source conductors outside the array of transistors. As mentioned above, this technique is equally applicable to the formation of transistors with other functions, such as transistors for a logic circuit, in which the electrical contacts may (or may not) be within a circuit area including transistors.

With reference to FIGS. 7 and 8: in one mass-production example, the workpiece on which the two upper gate dielectric layers 12c, 14b are formed includes a large area unit 40 (comprising a large area plastics support sheet) which is later cut (together with layers formed in situ on the unit 40) to produce a plurality of devices having a dimension (e.g. width) D1, D2 smaller than the corresponding dimension (e.g. width) of the large area unit 40. The large area unit 40 includes a conductor pattern which defines the above-mentioned source-drain conductor patterns for each of the plurality of devices, and the above-mentioned continuous layer of semiconductor channel material 8a extends continuously over substantially the whole area of the large area unit, before patterning as described above. This mass-production technique involves two depositions (under the same conditions and by the same deposition technique) of controlled amounts of solution of the above-mentioned cross-linkable material substantially uniformly across the whole area of the large area unit 40, with intermediate curing and surface treatment between the two depositions; and after the second curing operation, the resulting two gate dielectric layers 12b, 14b each occupy substantially the whole area of the large area unit 40. As mentioned above, the technique does not exclude subsequent patterning of one or both of the two gate dielectric layers 12c, 14b; and such later patterning may be employed, for example, to create via holes down to the drain conductors 6 to facilitate conductive connections between the drain conductors 6 and respective pixel electrodes formed at a later stage.

The inventors for the present application have found that the above-described technique results in a production process with better yield, compared to an otherwise identical technique in which the two gate dielectric layers 12c, 14b having the same composition are replaced by a single upper gate dielectric layer having the same composition as the two upper gate dielectric layers 10b, 12c and having substantially the same thickness as the combined thickness of the two upper gate dielectric layers 12c, 14b. The inventors for the present application have attributed this improvement in yield to two factors: (i) better cross-linking of the cross-linkable material; and (ii) a reduction in the contribution by pinholes in the gate dielectric to leakage currents between the semiconductor and the gate electrode. For the latter, the inventors for the present application believe that the above-described surface treatment of the upper surface of the lower one of the two gate dielectric layers has the effect of better preventing the propagation of pinholes (arising from the solution deposition process) in the lower one of the two gate dielectric layers into and through the upper one of the two gate dielectric layers.

The above-mentioned improvement in cross-linking may also be achieved to some extent when performing curing other than via an irradiative technique, such as a thermal curing technique involving heating the workpiece by thermal conduction.

Electronic devices (such as e.g. transistors, transistor arrays and/or capacitors) produced by the technique described above may be used in a wide range of devices, such as e.g. display devices, sensor devices and logic circuits.

In addition to any modifications explicitly mentioned above, it will be evident to a person skilled in the art that various other modifications of the described embodiment may be made within the scope of the invention.

The applicant hereby discloses in isolation each individual feature described herein and any combination of two or more such features, to the extent that such features or combinations are capable of being carried out based on the present specification as a whole in the light of the common general knowledge of a person skilled in the art, irrespective of whether such features or combinations of features solve any problems disclosed herein, and without limitation to the scope of the claims. The applicant indicates that aspects of the present invention may consist of any such individual feature or combination of features.

1. A method of forming a stack of layers defining one or more electronic devices, the method comprising: depositing a first thickness of curable, dielectric or dielectric precursor material over an area of a workpiece; thereafter exposing the workpiece to curing conditions at least over said area of said workpiece; and without any intermediate patterning operation, thereafter depositing a second thickness of said curable material over said area of said workpiece; and thereafter again exposing the workpiece to curing conditions at least over said area of said workpiece.

2. The method according to claim 1, wherein said one or more electronic devices include one or more transistors and said dielectric or dielectric precursor material is a gate dielectric or gate dielectric precursor material.

3. The method according to claim 1, wherein exposing the workpiece to curing conditions comprises exposing the workpiece to curing radiation at least over said area of said workpiece.

4. The method according to claim 1, wherein the first and second thicknesses are substantially equal.

5. The method according to claim 3, wherein the curable material is a cross-linkable material, and the curing radiation is at one or more wavelengths that induce cross-linking of the cross-linkable material.

6. The method according to claim 1, comprising: after said first curing and before depositing said second thickness of said curable material, subjecting the workpiece to a surface treatment at least over said area of said workpiece.

7. The method according to claim 6, wherein: depositing said second thickness of curable material comprises forming a film of a solution of said curable material; and said surface treatment increases the wettability of the surface of the workpiece for said solution of said curable material over said area of said workpiece.

8. The method according to claim 7, wherein said surface treatment comprises exposing the workpiece to a plasma or ultraviolet radiation from an ultraviolet lamp, at least over said area of said workpiece.

9. The method according to claim 1, wherein before depositing said first thickness of curable material, the workpiece includes a semiconductor channel material layer providing the semiconductor channels for said one or more transistors.

10. The method according to claim 9, wherein said semiconductor channel material layer is a patterned layer, and wherein forming said patterned semiconductor channel material layer comprises patterning a layer of semiconductor channel material via a dielectric layer; and wherein the method comprises depositing said first thickness of said curable material on said dielectric layer.

11. A method of forming a stack of layers defining one or more electronic devices, the method comprising: depositing a controlled amount of a solution of dielectric material or dielectric precursor material on a workpiece over an area of the workpiece, and thereafter depositing a second controlled amount of said solution of a dielectric material or a dielectric precursor material on the workpiece over said area of the workpiece; wherein prior to depositing said second controlled amount of said solution of dielectric material or dielectric precursor material, subjecting the workpiece to a surface treatment so as to increase the wettability of the surface of the workpiece for said solution of gate dielectric material or gate dielectric precursor material over said area of the workpiece.

12. The method according to claim 11, wherein said one or more electronic devices include one or more transistors and said dielectric or dielectric precursor material is a gate dielectric or gate dielectric precursor material.

13. The method according to claim 11, wherein said surface treatment comprises exposing said workpiece to a plasma or ultraviolet radiation from an ultraviolet lamp.
